(19) United States
(12) Patent Application Publication
(10) Pub. No.: US 2025/0126950 A1
(43) Pub. Date: Apr. 17, 2025

(54) MICRO LED DISPLAY PANEL

(71) Applicant: JADE BIRD DISPLAY (SHANGHAI) LIMITED, SHANGHAI (CN)

(72) Inventors: Jin CAO, Shanghai (CN); Jian GUO, Shanghai (CN)

(21) Appl. No.: 18/911,286

(22) Filed: Oct. 10, 2024

(30) Foreign Application Priority Data
Oct. 13, 2023 (WO) PCT/CN2023/124491

(51) Int. Cl. H01L 27/15; H01L 33/00; H01L 33/06; H01L 33/24; H01L 33/30; H01L 33/38; H01L 33/42; H01L 33/46; H01L 33/58; H01L 33/62

(52) U.S. Cl. CPC H10H 29/142; H10H 20/013; H10H 20/812; H10H 20/821; H10H 20/8314; H10H 20/833; H10H 20/855; H10H 20/857; H10H 20/0364; H10H 20/824; H10H 20/841

(57) ABSTRACT

A micro LED display panel includes a micro LED array area including a plurality of micro LED structures, wherein the plurality of micro LED structures includes a first group micro LED structures and a second group micro LED structures; a plurality of isolation contacts corresponding to the first group micro LED structures, one of the isolation contacts being formed at a bottom of each of first micro LED structure in the first group micro LED structures; and a plurality of conductive bottom contacts corresponding to the second group micro LED structures, one of the conductive bottom contacts being formed at a bottom of each of second micro LED structures in the second group micro LED structures.

### CROSS-REFERENCE TO RELATED APPLICATIONS

The present disclosure claims the benefits of priority to PCT Application No. PCT/CN2023/124491, filed on Oct. 13, 2023, which is incorporated herein by reference in its entirety.

### TECHNICAL FIELD

The present disclosure generally relates to micro display technology, and more particularly, to a micro light emitting diode (LED) display panel.

### BACKGROUND

Inorganic micro pixel light emitting diodes, also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A micro LED display panel is manufactured by integrating an array of thousands or even millions of micro LEDs with an integrated circuit (IC) back panel. Each pixel of the micro LED display panel is formed by one or more micro LEDs. The micro LED display panel can be a mono-color or multi-color panel. In particular, for a multi-color LED panel, each pixel may further include multiple sub-pixels formed by multiple micro LEDs, each of which corresponds to a different color. For example, three micro LEDs respectively corresponding to red, green, and blue colors may be superimposed to form one pixel. The different colors can be mixed to produce a broad array of colors.

Generally, all the micro LEDs in the micro LED array in the micro LED display panel are controlled to be global light or global black as a whole, or each micro LED is individually controlled to display image patterns. Therefore, energy consumption, electrical power and temperature of the micro LED display panel are increased.

### SUMMARY OF THE DISCLOSURE

Embodiments of the present disclosure provide a micro LED display panel. The micro LED display panel includes a micro LED array area including a plurality of micro LED structures, wherein the plurality of micro LED structures includes a first group micro LED structures and a second group micro LED structures; a plurality of isolation contacts corresponding to the first group micro LED structures, one of the isolation contacts being formed at a bottom of each of first micro LED structures in the first group micro LED structures; and a plurality of conductive bottom contacts corresponding to the second group micro LED structures, one of the conductive bottom contacts being formed at a bottom of each of second micro LED structures in the second group micro LED structures.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural diagram showing a sectional view of an exemplary micro LED display panel, according to some embodiments of the present disclosure.

FIG. 2 illustrates a structural diagram showing a top view of an exemplary micro LED display panel illustrating a first group micro LED structures and a second group micro LED structures, according to some embodiments of the present disclosure.

FIG. 3 illustrates a structural diagram showing a sectional view of a variant of the micro LED display panel shown in FIG. 1, according to some embodiments of the present disclosure.

FIG. 4 illustrates a structural diagram showing a sectional view of another exemplary micro LED display panel, according to some embodiments of the present disclosure.

FIG. 5 illustrates a structural diagram showing a top view of an exemplary micro LED display panel, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

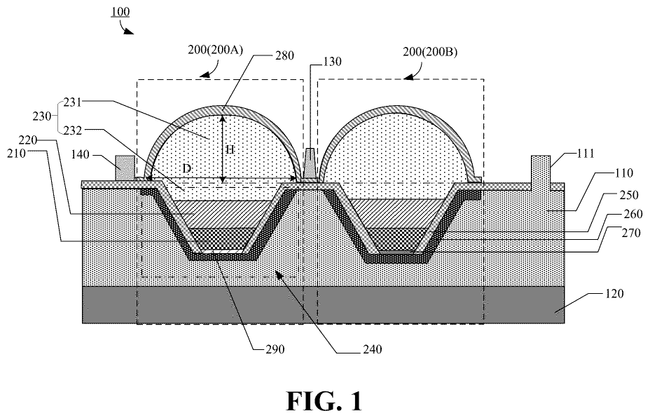

FIG. 1 illustrates a structural diagram showing a sectional view of an exemplary micro LED display panel 100, according to some embodiments of the present disclosure. Referring to FIG. 1, micro LED display panel 100 includes a micro LED array area including a plurality of micro LED structures 200. The plurality of micro LED structures 200 include a first group micro LED structures 200A and a second group micro LED structures 200B. In this example, one micro LED structure 200A in the first group and one micro LED structure 200B in the second group are shown only for descriptive purposes. It can be understood that additional micro LED structures can be incorporated in the first group micro LED structures and the second group micro LED structures in micro LED display panel 100. Micro LED display panel 100 further includes a bonding layer 110 and a substrate 120. Bonding layer 110 is formed between adjacent micro LED structures 200 and at a bottom of micro LED structures 200, and substrate 120 is formed at a bottom of bonding layer 110. Bonding layer 110 is bonded with substrate 120. Micro LED structure 200A in the first group further includes an isolation contact 290 provided at a bottom of micro LED structure 200A to electrically isolate micro LED structure 200A from bonding layer 110. A material of isolation contact 290 can be selected from one or more of silicon oxide, silicon nitride, alumina, etc. Micro LED structure 200B in the second group further includes a conductive bottom contact 270 provided at a bottom of micro LED structure 200B to electrically connect micro LED structure 200B with bonding layer 110. In some embodiments, a material of substrate 120 is Si. With the above-described structure, bonding layer 110 can connect all the micro LED structures 200B in the second group micro LED structures of micro LED display panel 100 to substrate 120, while micro LED structures 200A in the first group micro LED structures are not connected to substrate 120. As a result, micro LED structures 200A in the first group micro LED structures are always disabled. Therefore, energy consumption, electrical power, and temperature of micro LED display panel 100 can be reduced during operation for both working status and standby status.

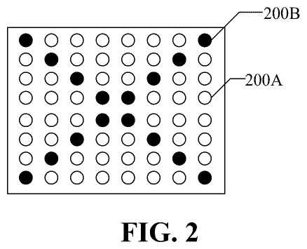

FIG. 2 illustrates a structural diagram showing a top view of an exemplary micro LED display panel illustrating the first group micro LED structures 200A and the second group micro LED structures 200B, according to some embodiments of the present disclosure. As shown in FIG. 2, the second group micro LED structures 200B form an image pattern. In this example, the image pattern is an X. Therefore, when micro LED display panel 100 is in working status, only the second group micro LEDs structures 200B are lighted and an image of X is displayed. There is no energy consumption by the first group micro LED structures 200A. Therefore, energy consumption, electrical power, and temperature of micro LED display panel 100 are reduced. During manufacturing a micro LED display panel, first group micro structures 200A is disabled by providing isolation contact 290 at a bottom of micro structure 200A, therefore, specific patterns can be obtained without additional manufacturing processes, which can simplify the manufacture process and reduce the cost.

Referring again to FIG. 1, in some embodiments, each micro LED structure 200 includes a first type epitaxial layer 210, a light emitting layer 220, and a second type epitaxial layer 230. Light emitting layer 220 is formed on first type epitaxial layer 210, and second type epitaxial layer 230 is formed on light emitting layer 220. First type epitaxial layer 210 is a P-type epitaxial layer. A material of first type epitaxial layer 210 is selected from one or more of GaN, AlGaN, GaP, AlGaInP, or AlInP. Light emitting layer 220 is a quantum well layer. A material of light emitting layer 220 is selected from one or more of InGaN, AlGaN, or AlGaInP.

Second type epitaxial layer 230 further includes a micro lens structure 231 and a bottom structure 232 on light emitting layer 220. Micro lens structure 231 is configured to adjust light emitting angles. Micro lens structure 231 and bottom structure 232 form an integrated structure. That is, during manufacturing, second type epitaxial layer 230 can be etched to form micro lens structure 231 and bottom structure 232. Materials of micro lens structure 231 and bottom structure 232 are the same. Second type epitaxial layer 230 is an N-type epitaxial layer. A material of second type epitaxial layer 230 is selected from one or more of AlInP, AlGaInP, GaN, or AlGaN.

In some embodiments, micro lens structure 231 is semi-spherical, conical, pyramidal, cylindrical, or circular truncated conical. A height H of micro lens structure 231 is in a range of 0.05 μm to 10 μm, and a diameter D of a bottom cross section of micro lens structure 231 is in a range of 0.5 μm to 10 μm.

With this structure, micro lens structure 231 can be etched from second type epitaxial layer 230 so that the manufacture process is simplified, which may reduce cost and improve productively.

In some embodiments, a size of micro lens structure 231 and a thickness of bottom structure 232 can be adjusted to obtain a better light emission performance. Since material of micro lens structure 231 is selected from one or more of AlInP, AlGaInP, GaN, or AlGaN, light emission efficiency can be increased by 15% to 18% compared with other micro lenses.

In this embodiments, bonding layer 110 is formed between adjacent mesa structures 240 of adjacent micro LED structures. As shown in FIG. 1, mesa structure 240 includes first type epitaxial layer 210, light emitting layer 220, and bottom structure 232 of second type epitaxial layer 230. In some embodiments, a sidewall of mesa structure 240 is inclined.

In some embodiments, micro LED structure 200 further includes a passivation layer 250 formed on a sidewall surface of mesa structure 240. In some embodiments, passivation layer 250 is further formed on a top surface of bonding layer 110. Passivation layer 250 is configured to provide protection for mesa structure 240 during manufacturing. A material of passivation layer 250 can be selected from one or more of SiO₂, Si₃N₄, or Al₂O₃. Bonding layer 110 further includes a top pad 111 projecting through passivation layer 250. Top pad 111 is configured to serve as an electrode to receive signal for controlling micro LED structure 200.

In some embodiments, micro LED structure 200 further includes a reflective layer 260 formed on a sidewall surface of passivation layer 250. In some embodiments, reflective layer 260 is further formed on a bottom of each mesa structure 240. A material of reflective layer 260 can be selected from one or more of Al, Ag, Ti, Pt, Au, Ni, Cr, or Sn.

Reflective layer 260 can reflect light towards micro lens structure 231, thereby improving the light emission efficiency. For example, the light emission efficiency can increase 40% to 100%.

In some embodiments, conductive bottom contact 270 is formed on the bottom of mesa structure 240, i.e., on a bottom of first type epitaxial layer 210, and on an inner surface of reflective layer 260. Conductive bottom contact 270 is connected with reflective layer 260 and bonded with bonding layer 110. A material of conductive bottom contact 270 is selected from one or more of ITO (Indium Tin Oxide), AZO (Al doped ZnO), GZO (Ga doped ZnO), Ge, Cr, Ni, Ti, Pt, Au, etc.

In some embodiments, micro LED structure 200 further includes a top transparent conductive layer 280 formed on a surface of micro lens structure 231. Top transparent conductive layer 280 is selected from one or more of ITO, AZO, or GZO. A thickness of top transparent conductive layer 280 is in a range of 5 nm to 500 nm. Since a refractivity of top transparent conductive layer 280 is between a refractivity of second type epitaxial layer 230 and a refractivity of air, top transparent conductive layer 280 formed on the surface of micro lens structure 231 can reduce energy loss, e.g., Fresnel reflection loss, of the light emission. In some embodiments, top transparent conductive layer 280 continuously covers a whole surface of second type epitaxial layer 230. Therefore, top transparent conductive layer 280 can connect all the micro LED structures 200 in micro LED display panel 100 and provide electrical conductivity for micro LED structure 200.

Micro LED display panel 100 further includes a top contact 130 on top transparent conductive layer 280 between the adjacent micro lens structures 231. In some embodiments, micro LED display panel 100 further includes an electrode pad 140 formed on an edge of the micro LED array area and connected with top transparent conductive layer 280.

As shown in FIG. 1, a sidewall of top transparent conductive layer 280 is connected with a sidewall of electrode pad 140. A top of electrode pad 140 is higher than a top of the end of top transparent conductive layer 280. In some embodiments, electrode pad 140 and top contact 130 are interconnected, for example, electrode pad 140 and top contact 130 are interconnected to form a mesh, to improve conductive connection performance for top transparent conductive layer 280. Electrode pad 140 and top pad 111 can be configured to receive a control signal, for example, from a signal source, to control micro LED display panel 100. For example, electrode pad 140 and top pad 111 can be connected with an external circuit to receive control signals to control micro LED display panel 100.

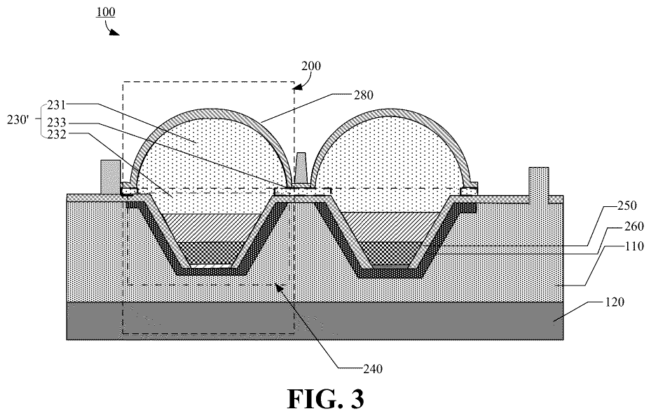

FIG. 3 illustrates a structural diagram showing a sectional view of a variant of micro LED display panel 100, according to some embodiments of the present disclosure. As shown in FIG. 3, a second type epitaxial layer 230′ further includes, in addition to micro lens structure 231 and bottom structure 232, an extrusion portion 233 interconnected between adjacent micro LED structures 200. Extrusion portion 233 extends along a horizontal direction. Passivation layer 250 is formed on a bottom surface of extrusion portion 233 and on a sidewall surface of mesa structure 240.

As shown in FIG. 3, reflective layer 260 is formed on a sidewall surface of passivation layer 250 and on at least part of the bottom surface of passivation layer 250 under the bottom surface of extrusion portion 233.

In some embodiments, top transparent conductive layer 280 is formed on a surface of micro lens structure 231 and on a top surface of extrusion portion 233.

Description of other features of micro LED display panel 100 may be found by referring to such features described above with reference to FIG. 1, which will not be repeated here.

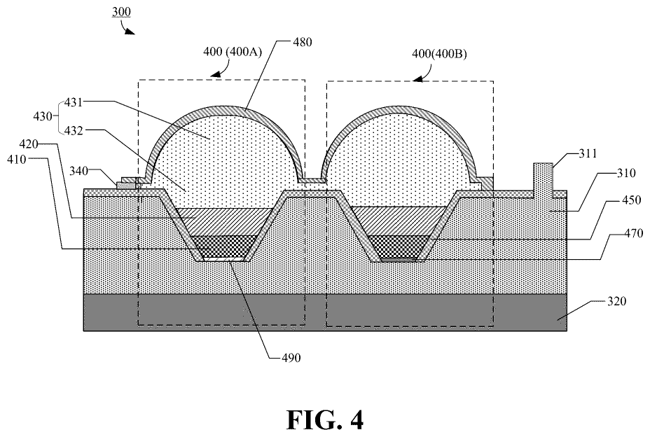

FIG. 4 illustrates a structural diagram showing a sectional view of another micro LED display panel 300, according to some embodiments of the present disclosure. As shown in FIG. 4, micro LED display panel 300 includes a plurality of micro LED structures 400. The plurality of micro LED structures 400 include a first group micro LED structures 400A and a second group micro LED structures 400B. In this example, one micro LED structure 400A in the first group and one micro LED structure 400B in the second group are shown only for descriptive purposes. It can be understood that additional micro LED structures can be incorporated in the first group micro LED structures and the second group micro LED structures of micro LED display panel 300. Micro LED display panel 300 further a bonding layer 310, and a substrate 320 formed at a bottom of bonding layer 310 and bonded with bonding layer 310. Micro LED structure 400A in the first group further includes an isolation contact 490 provided at a bottom of micro LED structure 400A to electrically isolate micro LED structure 400A from bonding layer 310. A material of isolation contact 490 is selected from one or more of silicon oxide, silicon nitride, alumina, etc. Micro LED structure 400B in the second group further includes a bottom contact 470 formed at a bottom of a first type epitaxial layer 410 and bonded with bonding layer 310 to electrically connect micro LED structure 400 with bonding layer 310. In this example, there is no reflective layer provided.

Still referring to FIG. 4, in this embodiment, an end of a top transparent conductive layer 480 is formed on part of a top of an electrode pad 340 and on a sidewall of electrode pad 340. Electrode pad 340 is provided for connecting to an external circuit.

Description of other features of micro LED display panel 300 may be found by referring to similar features described above with reference to FIG. 1 for micro LED display panel 100, which will not be repeated here.

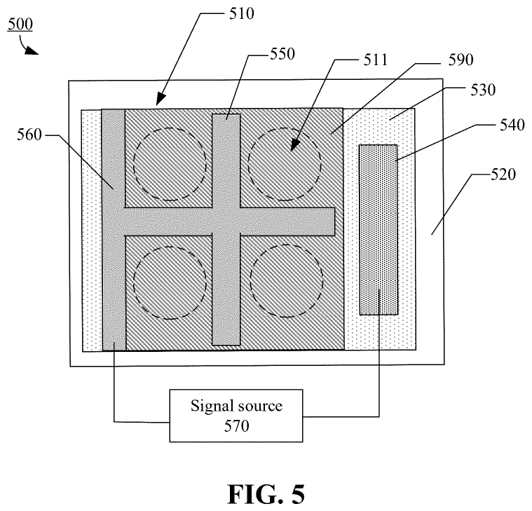

FIG. 5 illustrates a structural diagram showing a top view of a micro LED display panel 500, according to some embodiments of the present disclosure. Referring to FIG. 5, micro LED display panel 500 includes a micro LED array area 510 and a substrate 520 (e.g., substrate 120 in FIG. 1 or substrate 320 in FIG. 4). Micro LED array area 510 is located on substrate 520 to form an image display area of micro LED display panel 500. The rest of the area on substrate 520 not covered by micro LED array area 510 is formed as a non-functional area. Substrate 520 is formed at the back surface of micro LED array area 510 with a part extending outside of, i.e., not covered by, micro LED array area 510. Micro LED array area 510 includes a plurality of micro LED structures 511 (e.g., micro LED structures 200 in FIG. 1 or micro LED structures 400 in FIG. 4) provided in an array. It can be understood that in FIG. 5, micro LED array area 510 including 2×2 micro structures is shown only for illustrative purpose. Substrate 520 is configured to control the plurality of micro LED structures 511.

In some embodiments, a top transparent conductive layer 590 (for example, top transparent conductive layer 280 in FIG. 1 or top transparent conductive layer 480 in FIG. 4) of micro LED structure 511 is interconnected with each of the plurality of micro LED structures 511. That is, top transparent conductive layer 590 is continuously formed on a top of micro LED array area 510, and connected with every micro LED structure 511. An electrode pad 560 (e.g., electrode pad 140 in FIG. 1 or electrode pad 340 in FIG. 4) is formed on an edge of micro LED array area 510 and connected with top transparent conductive layer 590. In some embodiments, a top contact 550 (e.g., top contact 130 in FIG. 1) is provided on top transparent conductive layer 590 between the adjacent micro LED structures 511. As shown in FIG. 5, electrode pad 560 and top contact 550 are interconnected. A top pad 540 (e.g., top pad 111 in FIG. 1 or top pad 311 in FIG. 4) is provided to electrically connect with substrate 520.

In some embodiments, micro LED display panel 500 further includes a signal source 570 electrically connected with substrate 520 and the top transparent conductive layer 590. For example, signal source 570 electrically connected with top pad 540 and electrode pad 560.

Each micro LED structure herein (e.g., micro LED structure 200 in FIG. 1 and micro LED structure 400 in FIG. 4) has a very small volume. The light emitting area of the micro LED display panel, e.g., micro LED display panel 500, is very small, such as 1 mm×1 mm, 3 mm×5 mm, etc. In some embodiments, the light emitting area is the area of the micro LED array area in the micro LED display panel. Micro LED display panel 500 includes one or more micro LED structures 511 that form a pixel array in which the micro LED structures are pixels, such as a 1600×1200, 680×480, or 1920×1080-pixel array. The diameter of each micro LED is in the range of about 200 nm to 2 μm.

Different types of micro LED panels can be provided. For example, the resolution of a display panel can range typically from 8×8 to 3840×2160. Common display resolutions include QVGA (Quarter Video Graphics Array) with 320×240 resolution and an aspect ratio of 4:3, XGA (Extended Graphics Array) with 1024×768 resolution and an aspect ratio of 4:3, D (Definition) with 1280×720 resolution and an aspect ratio of 16:9, FHD (Full High Definition) with 1920×1080 resolution and an aspect ratio of 16:9, UHD (Ultra High Definition) with 3840×2160 resolution and an aspect ratio of 16:9, and 4K with 4096×2160 resolution. There can also be a wide variety of pixel sizes, ranging from sub-micron and below to 10 mm and above. The size of the overall display region can also vary widely, ranging from diagonals as small as tens of microns or less up to hundreds of inches or more.

The embodiments may further be described using the following clauses:

1. A micro LED display panel, comprising:
a micro LED array area including a plurality of micro LED structures, wherein the plurality of micro LED structures include a first group micro LED structures and a second group micro LED structures;
a plurality of isolation contacts corresponding to the first group micro LED structures, one of the isolation contacts being formed at a bottom of each of first micro LED structures in the first group micro LED structures; and
a plurality of conductive bottom contacts corresponding to the second group micro LED structures, one of the conductive bottom contacts being formed at a bottom of each of second micro LED structures in the second group micro LED structures.

2. The micro LED display panel according to clause 1, further comprising:
a bonding layer formed between adjacent micro LED structures and at a bottom of the plurality of micro LED structures; and
a substrate formed at a bottom of the bonding layer, wherein the bonding layer is bonded with the substrate.

3. The micro LED display panel according to clause 1, wherein the second group micro LED structures form an image pattern.

4. The micro LED display panel according to clause 2, wherein the micro LED structure comprises:
a first type epitaxial layer;
a light emitting layer formed on the first type epitaxial layer;
a second type epitaxial layer formed on the light emitting layer, wherein the second type epitaxial layer further comprises:
   a micro lens structure and a bottom structure, the micro lens structure and the bottom structure being an integrated structure;
wherein a mesa structure comprises the first type epitaxial layer, the light emitting layer, and the bottom structure of the second type epitaxial layer, the bonding layer being formed between adjacent mesa structures of the adjacent micro LED structures.

5. The micro LED display panel according to clause 4, wherein a sidewall of the mesa structure is inclined.

6. The micro LED display panel according to clause 4 or 5, wherein the micro LED structure further comprises: a passivation layer formed on a sidewall surface of the mesa structure.

7. The micro LED display panel according to clause 6, wherein the passivation layer is further formed on a top surface of the bonding layer.

8. The micro LED display panel according to clause 7, wherein the bonding layer comprising a top pad projecting through the passivation layer.

9. The micro LED display panel according to any one of clauses 6 to 8, wherein a material of the passivation layer is selected from one or more of SiO₂, Si₃N₄, or Al₂O₃.

10. The micro LED display panel according to clause 6, wherein the micro LED structure further comprises a top transparent conductive layer formed on a surface of the micro lens structure.

11. The micro LED display panel according to clause 10, wherein a material of the top transparent conductive layer is selected from one or more of ITO (Indium Tin Oxide), AZO (Al doped ZnO), or GZO (Ga doped ZnO).

12. The micro LED display panel according to clause 10, wherein the top transparent conductive layer continuously covers a whole surface of the second type epitaxial layer.

13. The micro LED display panel according to clause 12, further comprising a top contact formed on the top transparent conductive layer between adjacent micro lens structures.

14. The micro LED display panel according to any one of clauses 10 to 13, wherein a thickness of the top transparent conductive layer is in a range of 5 nm to 500 nm.

15. The micro LED display panel according to clause 10, further comprising an electrode pad formed on an edge of the micro LED array area and connected with the top transparent conductive layer.

16. The micro LED display panel according to clause 15, wherein an end of the top transparent conductive layer is formed on part of a top of the electrode pad and on a sidewall of the electrode pad.

17. The micro LED display panel according to clause 15, wherein a sidewall of the top transparent conductive layer is connected with a sidewall of the electrode pad.

18. The micro LED display panel according to clause 15, wherein a top of the electrode pad is higher than a top of an end of the top transparent conductive layer.

19. The micro LED display panel according to clause 4, wherein a material of the first type epitaxial layer is selected from one or more of GaN, AlGaN, GaP, AlGaInP, or AlInP; a material of the second type epitaxial layer is selected from one or more of AlInP, AlGaInP, GaN, or AlGaN; and the light emitting layer is a quantum well layer.

20. The micro LED display panel according to clause 4, wherein the micro lens structure and the bottom structure are made of a same material.

21. The micro LED display panel according to clause 20, wherein the micro lens structure is semi-spherical, conical, pyramidal, cylindrical, or circular truncated conical.

22. The micro LED display panel according to clause 20, wherein a height of the micro lens structure is in a range of 0.05 μm to 10 μm, and a diameter of a bottom cross section of the micro lens structure is in a range of 0.5 μm to 10 μm.

23. The micro LED display panel according to clause 4, wherein the second type epitaxial layer further comprises: an extrusion portion interconnected between adjacent micro LED structures.

24. The micro LED display panel according to clause 23, wherein the extrusion portion extends along a horizontal direction.

25. The micro LED display panel according to clause 23, wherein the micro LED structure further comprises: a passivation layer formed on a bottom surface of the extrusion portion and on a sidewall surface of the mesa structure.

26. The micro LED display panel according to clause 25, wherein the micro LED structure further comprises: a top transparent conductive layer formed on a surface of the micro lens structure and on a top surface of the extrusion portion.

27. The micro LED display panel according to clause 6, wherein the micro LED structure further comprises a reflective layer formed on a sidewall surface of the passivation layer.

28. The micro LED display panel according to clause 27, wherein the reflective layer is further formed on a bottom of the mesa structure.

29. The micro LED display panel according to clause 28, wherein the conductive bottom contact is formed on the bottom of the mesa structure and on an inner surface of the reflective layer.

30. The micro LED display panel according to any one of clauses 27 to 29, wherein a material of the reflective layer is selected from one or more of Al, Ag, Ti, Pt, Au, Ni, Cr, or Sn.

31. The micro LED display panel according to clause 2, wherein a material of the substrate is Si.

It should be noted that the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED display panel, comprising:
a micro LED array area including a plurality of micro LED structures, wherein the plurality of micro LED structures include a first group micro LED structures and a second group micro LED structures;
a plurality of isolation contacts corresponding to the first group micro LED structures, one of the isolation contacts being formed at a bottom of each of first micro LED structures in the first group micro LED structures; and
a plurality of conductive bottom contacts corresponding to the second group micro LED structures, one of the conductive bottom contacts being formed at a bottom of each of second micro LED structures in the second group micro LED structures.

2. The micro LED display panel according to claim 1, further comprising:
a bonding layer formed between adjacent micro LED structures and at a bottom of the plurality of micro LED structures; and
a substrate formed at a bottom of the bonding layer, wherein the bonding layer is bonded with the substrate.

3. The micro LED display panel according to claim 1, wherein the second group micro LED structures form an image pattern.

4. The micro LED display panel according to claim 2, wherein the micro LED structure comprises:
a first type epitaxial layer;
a light emitting layer formed on the first type epitaxial layer;
a second type epitaxial layer formed on the light emitting layer, wherein the second type epitaxial layer further comprises:
a micro lens structure and a bottom structure, the micro lens structure and the bottom structure being an integrated structure;
wherein a mesa structure comprises the first type epitaxial layer, the light emitting layer, and the bottom structure of the second type epitaxial layer, the bonding layer being formed between adjacent mesa structures of the adjacent micro LED structures.

5. The micro LED display panel according to claim 4, wherein a sidewall of the mesa structure is inclined.

6. The micro LED display panel according to claim 4, wherein the micro LED structure further comprises: a passivation layer formed on a sidewall surface of the mesa structure.

7. The micro LED display panel according to claim 6, wherein the passivation layer is further formed on a top surface of the bonding layer.

8. The micro LED display panel according to claim 7, wherein the bonding layer comprising a top pad projecting through the passivation layer.

9. The micro LED display panel according to claim 6, wherein a material of the passivation layer is selected from one or more of SiO₂, Si₃N₄, or Al₂O₃.

10. The micro LED display panel according to claim 6, wherein the micro LED structure further comprises a top transparent conductive layer formed on a surface of the micro lens structure.

11. The micro LED display panel according to claim 10, wherein a material of the top transparent conductive layer is selected from one or more of ITO (Indium Tin Oxide), AZO (Al doped ZnO), or GZO (Ga doped ZnO).

12. The micro LED display panel according to claim 10, wherein the top transparent conductive layer continuously covers a whole surface of the second type epitaxial layer.

13. The micro LED display panel according to claim 12, further comprising a top contact formed on the top transparent conductive layer between adjacent micro lens structures.

14. The micro LED display panel according to claim 10, wherein a thickness of the top transparent conductive layer is in a range of 5 nm to 500 nm.

15. The micro LED display panel according to claim 10, further comprising an electrode pad formed on an edge of the micro LED array area and connected with the top transparent conductive layer.

16. The micro LED display panel according to claim 15, wherein an end of the top transparent conductive layer is formed on part of a top of the electrode pad and on a sidewall of the electrode pad.

17. The micro LED display panel according to claim 15, wherein a sidewall of the top transparent conductive layer is connected with a sidewall of the electrode pad.

18. The micro LED display panel according to claim 15, wherein a top of the electrode pad is higher than a top of an end of the top transparent conductive layer.

19. The micro LED display panel according to claim 4, wherein a material of the first type epitaxial layer is selected from one or more of GaN, AlGaN, GaP, AlGaInP, or AlInP; a material of the second type epitaxial layer is selected from one or more of AlInP, AlGaInP, GaN, or AlGaN; and the light emitting layer is a quantum well layer.

20. The micro LED display panel according to claim 4, wherein the micro lens structure and the bottom structure are made of a same material.

21. The micro LED display panel according to claim 20, wherein the micro lens structure is semi-spherical, conical, pyramidal, cylindrical, or circular truncated conical.

22. The micro LED display panel according to claim 20, wherein a height of the micro lens structure is in a range of 0.05 μm to 10 μm, and a diameter of a bottom cross section of the micro lens structure is in a range of 0.5 μm to 10 μm.

23. The micro LED display panel according to claim 4, wherein the second type epitaxial layer further comprises: an extrusion portion interconnected between adjacent micro LED structures.

24. The micro LED display panel according to claim 23, wherein the extrusion portion extends along a horizontal direction.

25. The micro LED display panel according to claim 23, wherein the micro LED structure further comprises: a passivation layer formed on a bottom surface of the extrusion portion and on a sidewall surface of the mesa structure.

26. The micro LED display panel according to claim 25, wherein the micro LED structure further comprises: a top transparent conductive layer formed on a surface of the micro lens structure and on a top surface of the extrusion portion.

27. The micro LED display panel according to claim 6, wherein the micro LED structure further comprises a reflective layer formed on a sidewall surface of the passivation layer.

28. The micro LED display panel according to claim 27, wherein the reflective layer is further formed on a bottom of the mesa structure.

29. The micro LED display panel according to claim 28, wherein the conductive bottom contact is formed on the bottom of the mesa structure and on an inner surface of the reflective layer.

30. The micro LED display panel according to claim 27, wherein a material of the reflective layer is selected from one or more of Al, Ag, Ti, Pt, Au, Ni, Cr, or Sn.

31. The micro LED display panel according to claim 2, wherein a material of the substrate is Si.
